(19) United States
(12) Patent Application Publication
(10) Pub. No.: US 2004/0179342 A1
(43) Pub. Date: Sep. 16, 2004

(54) Holster for a portable electronic device

(75) Inventors: David Raymond Pritchard, Winston-Salem, NC (US); John Thomas Gunn, Charlotte, NC (US)

Correspondence Address: MICHAEL BEST & FRIEDRICH LLP, 3773 CORPORATE PARKWAY, SUITE 360, CENTER VALLEY, PA, 18034-8217, US

(73) Assignee: Ingersoll-Rand Company, Woodcliff Lake, NJ (US)

(21) Appl. No.: 10/397,080

(22) Filed: Mar. 26, 2003

Related U.S. Application Data
(63) Continuation of application No. 29/177,539, filed on Mar. 11, 2003.

(51) Int. Cl. H05K 7/20

(52) U.S. Cl. 361/715

(57) ABSTRACT

A holster for an electronic device having a device length and a device width. The holster comprises a main body including a rear surface having a given periphery and a wall extending from the rear surface about a substantial portion of the periphery. A lip extends from the wall about a substantial portion of the periphery. An open area is defined by the lip and has an open area length and an open area width wherein the open area length is greater than the device length or the open area width is greater than the device width.

This application claims priority to U.S. patent application Ser. No. 29/177,539 filed on Mar. 11, 2003.

### BACKGROUND

The present invention relates to a holster for an electronic device. More particularly, the present invention relates to a holster for a portable electronic device, for example, a personal digital assistant.

### SUMMARY

The present invention provides a holster for an electronic device. The device has a device length and a device width. In a first aspect of the invention, the holster comprises a main body including a rear surface having a given periphery and a wall extending from the rear surface about a substantial portion of the periphery. A lip extends from the wall about a substantial portion of the periphery. An open area is defined by the lip and has an open area length and an open area width wherein the open area length is greater than the device length or the open area width is greater than the device width. Preferably, both the open area length is greater than the device length and the open area width is greater than the device width.

In a second aspect of the invention, the present invention provides a holster for an electronic device. The holster comprises a main body having a rear surface and side walls that define an internal retainment area configured to receive and substantially enclose the electronic device. A connection adapter extends through and is secured to the main body. The connection adapter includes a first connection port extending into the internal retainment area and a second connection port extending outward from the main body.

Other features and advantages of the present invention will be understood from the following description and associated drawings.

### BRIEF DESCRIPTION OF THE DRAWINGS

FIG. 1 is an exploded isometric view of a holster that is a first embodiment of the present invention with an illustrative electronic device prior to positioning in the holster;

FIG. 2 is an isometric view of the holster of FIG. 1 assembled;

FIG. 3 is a top plan view of the holster of FIG. 1 with the tether not shown for clarity;

FIG. 4 is a sectional view along line 4-4 in FIG. 3 with a coupling element shown prior to insertion in the holster;

FIG. 5 is a side elevational view of the holster of FIG. 1 in a stand position;

FIG. 6 is a side elevational view of the holster of FIG. 1 in a transport position;

FIG. 7 is a side elevational view of the holster of FIG. 1 in a carry position.

### DETAILED DESCRIPTION OF THE PREFERRED EMBODIMENTS

The present invention will be described with reference to the accompanying drawing figures wherein like numbers represent like elements throughout. Certain terminology, for example, “top”, “bottom”, “right”, “left”, “front”, “frontward”, “forward”, “back”, “rear” and “rearward”, is used in the following description for relative descriptive clarity only and is not intended to be limiting.

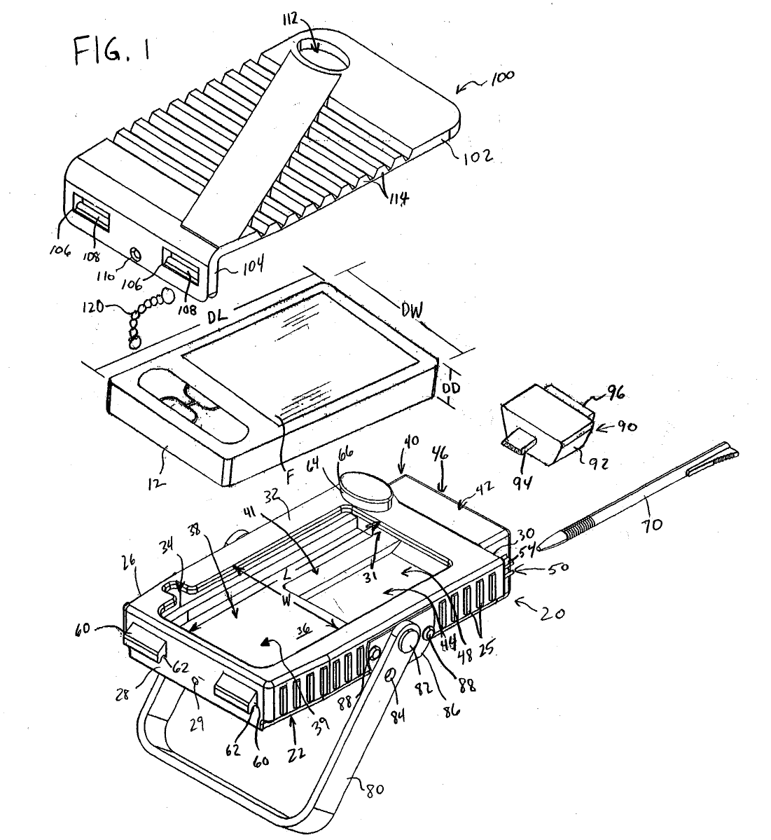

Referring to FIGS. 1-4, a holster 10 that is a preferred embodiment of the present invention will be described. The holster 10 is configured for use with a portable electronic device 12. The electronic device 10 can have various configurations and functions. For example, the electronic device 10 may be a personal digital assistant (“PDA”), a cellular phone or any other hand-held computer. As shown in FIG. 1, the intended electronic device 10 has a given length DL, a given width DW and a given depth DD.

The preferred holster 10 includes a holding compartment 20 and a cover 100. The holding compartment 20 has a main body 22 and an attachment portion 40 extending from the main body 22. The main body 22 is defined by a side walls 24, 26, a bottom wall 28 and top wall 30 extending generally perpendicularly from a rear surface 36. The walls 24, 26, 28, 30 and rear surface 36 define a retainment area 38 sized to receive the intended electronic device 12. While the retainment area 38 is preferably rectangular, the dimensions and configuration of the main body 22 may be varied to accommodate electronic devices 12 of various sizes and configurations.

A lip 32 extends from the walls 24, 26, 28, 30 around the perimeter of the retainment area 38 to retain the electronic device 12 within the retainment area 38. The lip 32 has a central open area 39 to allow passage of the electronic device 12 into the retainment area 38 and to allow access to and use of the electronic device 12 while positioned in the retainment area 38. The open area 39 has a length L and width W. The length L or the width W, or preferably both the length L and width W, are less than the corresponding dimensions of the electronic device 12 (DL, DW) such that the lip 32 overlaps a portion of the electronic device 12 and thereby retains the electronic device 12 in the retainment area 38. To help facilitate passage of the electronic device 12 into the retainment area 38, the lip 32 preferably has at least one cut out 34 to allow flexing of the lip 32 during insertion. The lip 32 has a thickness t such that the face F of the electronic device 12 is set back. The set back provides protection of the electronic device 12 face F in the event the holster 10 is dropped or the like. To further protect the electronic device 12, the side walls 24, 26 preferably have ribs 25 extending therefrom.

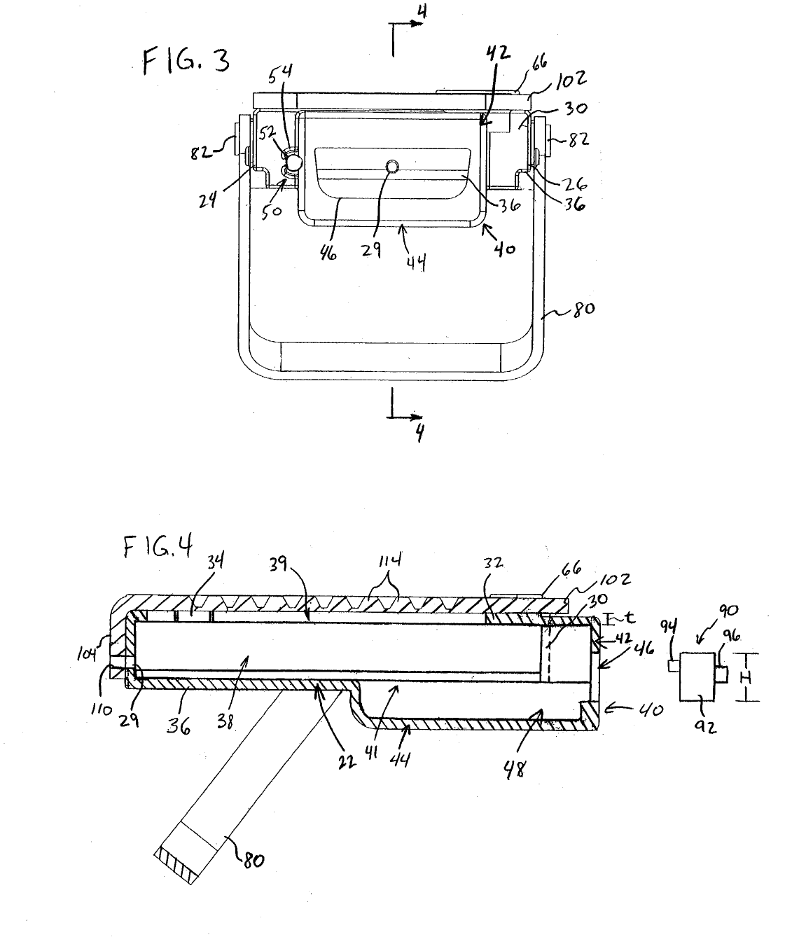

Referring to FIGS. 3 and 4, the attachment portion 40 of the holding compartment 20 will be described. The attachment portion 40 includes a connection portion 42 and a securement portion 44, together which define an internal area 48. The connection portion 42 extends from the top wall 30 and the securement portion 44 extends from the rear surface 36 of the main body 22. The top wall 30 has a central open area 31 and the rear surface 36 has a central open area 41. The open areas 31, 41 extend between the main body retainment area 38 and the internal area 48 such that a continuous open area is defined.

The connection portion 42 has an opening 46 configured to receive and secure a cable connection adapter 90. As can be seen in FIGS. 3 and 4, the opening 46 extends lower than rear surface 36 of the main body 22. The increased depth of the attachment portion 40 allows the connection adapter 90 to have a height H greater than the depth DD of the electronic device 12. The connection adapter 90 preferably has a body 92 configured to fit in and be secured in the opening 46 of the attachment portion 40. An electronic device port 94, configured to connect to an output port of the electronic device 12, extends from a first side of the connection adapter body 92. An external port 96 extends from the opposite side of the connection adapter body 92. Both ports 94, 96 may have various configurations, for example, USB or serial connections, and male or female connections. Upon securement of the connection adapter 90, the external port 96 extends from the holster 10 such that an external, easily accessible connection port is available.

The securement portion 44 extends from the rear surface 36 of the main body 22 and is configured for connection to a work belt (not shown) or the like. The connection means may have various configurations. For example, a clip or button may extend from the securement portion 44. Alternatively, the securement portion 44 may be formed with a groove or the like that is receivable in a tool belt slot.

Referring to FIG. 3, the main body 22 top wall 30 preferably includes a stylus retainer 50. The retainer 50 includes a through hole 52 through which a stylus 70 may be inserted. The through hole 52 is preferably positioned such that it aligns with a stylus receiving hole in the electronic device 12. The retainer 50 further comprises a clip 54 that receives and secures the stylus 70.

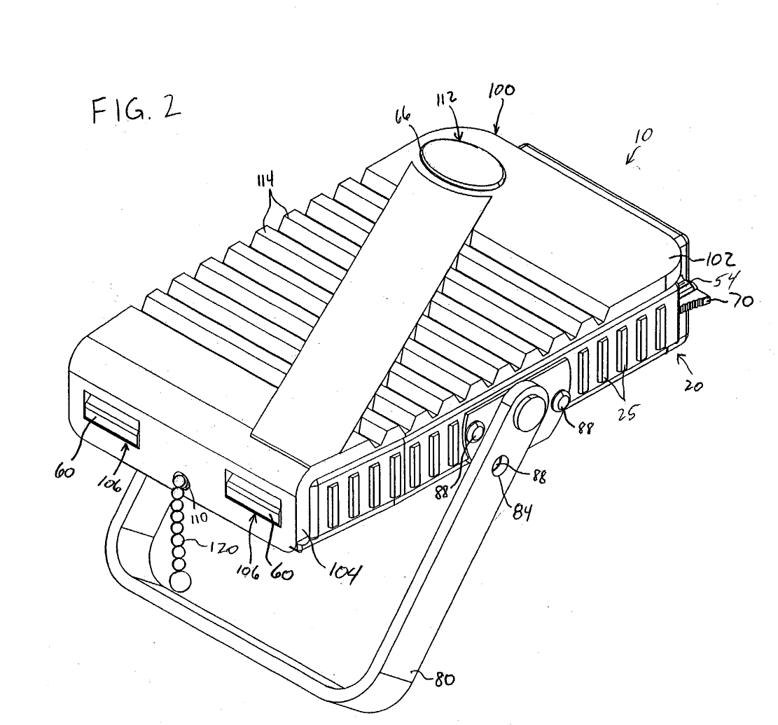

Referring to FIGS. 1 and 2, the cover 100 preferably includes a planar cover portion 102 with and attachment wall 104 extending therefrom. The cover 100 is removably connected to the holding compartment 20. The planar cover portion 102 is sized and configured to cover and substantially close the open area 39 of the main body 22. The planar cover portion 102 preferably includes a plurality of ribs 114 configured to absorb impact that might be asserted against the holster 10. The attachment wall 104 includes a pair of slots 106 configured to engage tabs 60 extending from the bottom wall 28 of the main body 22. Each slot 106 preferably has a protrusion 108 configured to be received in a groove 62 on the corresponding tab 60. The planar cover portion 102 includes a securement hole 112 configured to receive and retain a button 64 extending from the main body lip 32. The button 64 is preferably provided with a circumferential rim sized slightly larger than the securement hole 112 to provide secure engagement. To secure the cover 100 on the holding compartment 20, the tabs 60 are positioned in the corresponding cover slots 106 with the protrusions 108 received in the respective grooves 62. The securement hole 112 is then positioned about the button 64 with the rim 66 engaging the planar cover portion 102. A chain 120, tether, strap or other lanyard preferably extends between the cover 100 and the holding compartment 20 to retain the cover 100 when it is removed during use. The main body 22 and the cover 100 are preferably provided with aligned holes 29, 110, respectively, to facilitate attachment of the chain 120 or the like. In an alternative embodiment, the cover 100 is hingedly connected to the main body 22.

The holding compartment 20 and the cover 100 are preferably manufactured from a resilient material to provide protection for the electronic device 12. For example, the holding compartment 20 and a cover 100 may both be manufactured from natural material, like rubber, or a synthetic material. The components may be manufactured all from the same material or from different materials.

To facilitate transport and use of the electronic device 12 positioned in the holster 10, the main body 22 preferably has a handle 80 attached thereto. In the preferred embodiment, an attachment plate 86 is secured to each side wall 24, 26. A pivot pin 82 extends from each attachment plate 86 through a respective leg of the handle 80. Each attachment plate 86 has a series of protrusions 88 radially positioned about the pivot pin 82. A hole 84 in each handle leg is configured to receive a protrusion 88 to define a fixed position of the handle 80. Alternatively, the plate 86 may be provided with a series of detents and the handle leg may be provided with a protrusion or the like to be received in the detents. While the preferred embodiment has protrusions 88 on both sides of the holster 10, the protrusions may be provided on only one side. Furthermore, other configurations, for example, interengaging teeth or a retractable pin, may be utilized to set the handle postion.

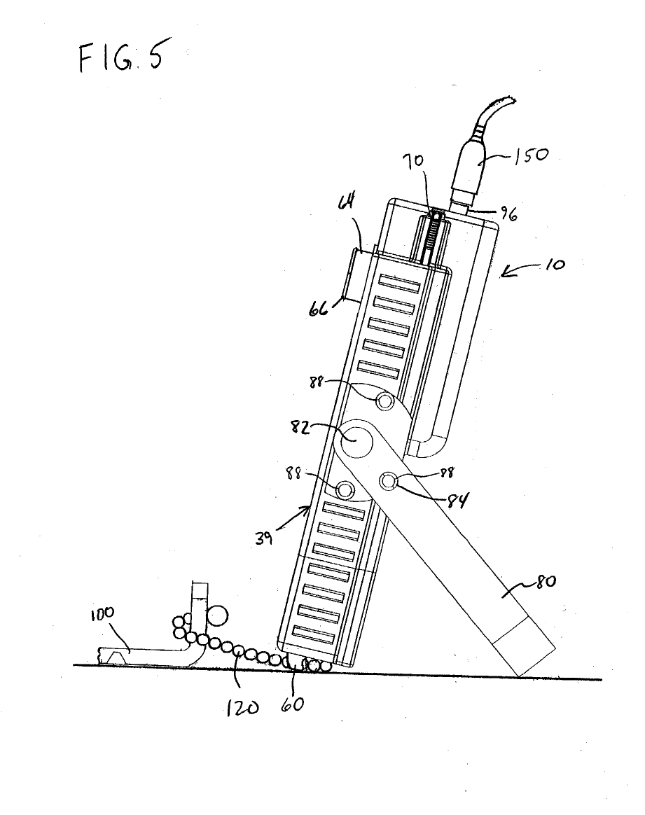

Referring to FIGS. 5-7, three preferred handle 80 positions defined by the protrusions 88 are illustrated. While three positions are shown, any number of protrusions 88 or detents can be provided on the plate 86 to define numerous handle 80 positions. FIG. 5 shows the holster 10 in a use position. The intermediate protrusion 88 is received in the hole 84 such that the handle 80 is maintained in an approximately 45 degree position. This position allows the holster 10 to be positioned on a table or the like for ease of use by a technician. The cover 100 can be removed with the open area 39, and thereby the face of the electronic device 12 (not shown), easily accessible. Furthermore, the external port 96 extends from the holster 10 such that an external cable 150 or the like can be easily attached to the electronic device 12. The opposite end of the cable 150 can be connected to machinery requiring programming or diagnosis, to a central data collection computer, an output device, or any other desired electronic components.

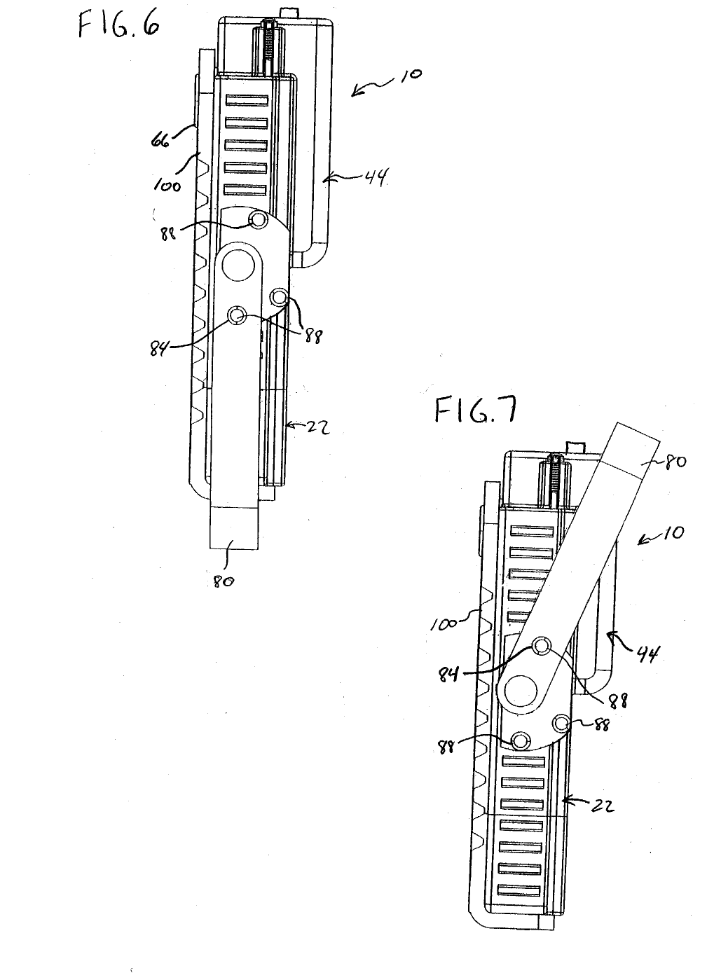

FIGS. 6 and 7 illustrate transport positions for the handle 80. As illustrated in FIG. 6, the handle 80 can be rotated such that the lower protrusion 88 is received in the handle hole 84. In this position, the handle 80 is generally out of the way, such that the securement portion 44 can be connected to a worker's belt or the like. As illustrated in FIG. 7, the handle 80 can be rotated such that the upper protrusion 88 is received in the handle hole 84. In this position, the handle 80 extends from the holster 10 such that the handle 80 can be utilized to carry the device 12.

What is claimed is:

1. A holster for an electronic device having a device length and a device width, the holster comprising:
a main body including
a rear surface having a given periphery;
a wall extending from the rear surface about a substantial portion of the periphery; and
a lip extending from the wall about a substantial portion of the periphery;
an open area defined by the lip, the open area having an open area length and an open area width wherein the open area length is greater than the device length or the open area width is greater than the device width.

2. A holster according to claim 1 wherein both the open area length is greater than the device length and the open area width is greater than the device width.

3. A holster according to claim 1 wherein the lip includes a cut out.

4. A holster according to claim 1 wherein the lip has a thickness t such that a face of the electronic device is recessed.

5. A holster according to claim 1 further comprising a cover attachable to the main body to removably cover the open area.

6. A holster according to claim 5 wherein the cover includes a planar surface that substantially covers the open area and wherein the planar surface includes a plurality of alternating ribs and grooves.

7. A holster according to claim 5 wherein the cover is hingedly connected to the main body.

8. A holster according to claim 5 wherein the main body and the cover are manufactured from resilient material.

9. A holster according to claim 1 wherein the main body further comprises an attachment portion extending from the rear surface.

10. A holster according to claim 9 wherein the attachment portion includes an internal area in communication with a retainment area defined by the rear surface and the wall.

11. A holster according to claim 10 wherein a cable connection adapter extends through the attachment portion into the internal chamber.

12. A holster according to claim 1 wherein at least a portion of the wall has a plurality of ribs extending outward therefrom.

13. A holster according to claim 1 further comprising a rotatable handle secured to the wall.

14. A holster according to claim 13 wherein the handle is moveable between at least first and second positions wherein in the first position the handle extends substantially parallel to the rear surface and in the second position the handle extends at an angle relative to the rear surface such that the holster can be placed on a surface with the open area at a working angle.

15. A holster for an electronic device, the holster comprising:
a main body having a rear surface and side walls that define an internal retainment area configured to receive and substantially enclose the electronic device; and
a connection adapter extending through and secured to the main body; the connection adapter including a first connection port extending into the internal retainment area and a second connection port extending outward from the main body.

16. A holster according to claim 15 further comprising a lip extending from the wall about a substantial portion of the retainment area.

17. A holster according to claim 15 wherein the main body further comprises an attachment portion extending from the rear surface.

18. A holster according to claim 17 wherein the attachment portion includes an internal area in communication with the retainment area.

19. A holster according to claim 18 wherein the attachment portion includes a through opening configured to receive and retain the connection adapter.

20. A holster according to claim 19 wherein a portion of the through opening is aligned with retainment area and a portion of the through opening is aligned with the internal area.

21. A holster according to claim 15 wherein the second connection port is a serial port.

22. A holster according to claim 15 wherein the second connection port is a USB port.
